(19) United States
(12) Patent Application Publication
(10) Pub. No.: US 2024/0347478 A1
(43) Pub. Date: Oct. 17, 2024

(54) SUBSTRATE ALPHA PARTICLE SHIELD FOR SEMICONDUCTOR PACKAGES

(71) Applicant: Micron Technology, Inc., Boise, ID (US)

(72) Inventors: Chen-Yu HUANG, Taichung City (TW); Chong Leong GAN, Butterworth (MY)

(21) Appl. No.: 18/507,801

(22) Filed: Nov. 13, 2023

Related U.S. Application Data
(60) Provisional application No. 63/383,612, filed on Nov. 14, 2022.

(51) Int. Cl. H01L 23/556; H01L 23/00; H01L 23/31; H01L 23/498; H01L 25/065; H10B 80/00

(52) U.S. Cl. CPC H01L 23/556; H01L 23/49822; H01L 23/3107; H01L 24/16; H01L 25/0652; H01L 2224/16227; H10B 80/00

(57) ABSTRACT

Implementations described herein relate to various semiconductor device assemblies. In some implementations, a semiconductor device assembly may include a substrate, a plurality of electrical contacts disposed on an outer surface of the substrate, a solder resist disposed on the outer surface of the substrate and including an opening defined by a plurality of edges and exposing the plurality of electrical contacts, and an alpha particle shield disposed proximate to at least one edge, of the plurality of edges.

### CROSS REFERENCE TO RELATED APPLICATION

This patent application claims priority to U.S. Provisional Patent Application No. 63/383,612, filed on Nov. 14, 2022, and entitled “SUBSTRATE ALPHA PARTICLE SHIELD FOR SEMICONDUCTOR PACKAGES.” The disclosure of the prior application is considered part of and is incorporated by reference into this patent application.

### TECHNICAL FIELD

The present disclosure generally relates to semiconductor devices and methods of forming semiconductor devices. For example, the present disclosure relates to a substrate alpha particle shield for semiconductor packages.

### BACKGROUND

A semiconductor package includes a casing that contains one or more semiconductor devices, such as integrated circuits. Semiconductor device components may be fabricated on semiconductor wafers before being diced into die and then packaged. A semiconductor package protects internal components from damage and includes means for connecting internal components to external components (e.g., a circuit board), such as via balls, pins, or leads. A semiconductor package is sometimes referred to as a semiconductor device assembly.

### BRIEF DESCRIPTION OF THE DRAWINGS

FIG. 1 is a diagram of an example apparatus that may be manufactured using techniques described herein.

FIG. 2 is a diagram of an example memory device that may be manufactured using techniques described herein.

FIG. 3 is a diagram of an example apparatus (e.g., memory device) that includes an alpha particle shield.

FIG. 4 is a diagram showing a close-up view of a portion of the apparatus of FIG. 3.

FIGS. 5A-5I shows an example of a manufacturing process that may be used to manufacture the apparatus of FIG. 3.

FIG. 6 is a diagram of example equipment used to manufacture various semiconductor packages, memory devices, or similar components described herein.

FIG. 7 is a flowchart of an example method of forming an integrated assembly or memory device having an alpha particle shield.

FIG. 8 is a flowchart of an example method of forming an integrated assembly or memory device having an alpha particle shield.

FIG. 9 is a flowchart of an example method of forming an integrated assembly or memory device having an alpha particle shield.

FIG. 10 is a flowchart of an example method of forming an integrated assembly or memory device having an alpha particle shield.

### DETAILED DESCRIPTION

A memory package is a semiconductor package that includes various memory components in a casing. For example, a memory package may include a controller, one or more memory dies, and similar components mounted to a substrate. In some examples, certain radioactive impurities in materials used in memory packages may emit alpha particles that can cause soft errors in the controller, memory dies, or similar components of the memory package. For example, the substrate may include a base material that includes pre-impregnated fibers in a partially cured polymer matrix (sometimes referred to as “prepreg”), which may further be coated with a solder resist material. Radioactive impurities in one or more of the materials used to create the prepreg and/or solder resist may emit alpha particles or other radioactive particles. For example, a substrate (e.g., a prepreg substrate) and/or a solder resist applied thereto may include one or more of radioactive uranium isotopes (e.g., Uranium-238 (²³⁸U) or Uranium-235 (²³⁵U)) or radioactive thorium isotopes (e.g., Thorium-232 (²³²Th)), which may be a source of alpha particles in the memory package.

In such examples, if alpha particles emitted by the substrate and/or solder resist reach one or more integrated circuits of a memory package (e.g., a controller, a memory die, or a similar integrated circuit), the alpha particles may result in a soft error at the one or more integrated circuits. A soft error may refer to a temporary malfunction occurring within an otherwise normal semiconductor device (e.g., an undamaged integrated circuit) caused by the interaction of a radioactive ray with the semiconductor device. For example, radiation rays (e.g., alpha particles, cosmic rays, or similar radiation rays) entering an integrated circuit of a semiconductor device may generate a charged particle within the integrated circuit, resulting in data distortion and thus generating a soft error.

In some examples, one or more integrated circuits in a memory package may be mounted to the substrate via a plurality of bump bonds (e.g., a grid of solder balls), a plurality of pillar bonds, or other types of bonds. The bump bonds, pillar bonds, or similar bonds may elevate the integrated circuits with respect to an outer surface of the substrate. For example, the bump bonds, pillar bonds, or similar bonds may elevate a controller, memory dies, and/or or other electrical components above the solder resist applied to an outer surface of the substrate. In such cases, if a sufficiently large spacing is provided between a component (e.g., an integrated circuit) and the substrate and/or solder resist, a risk of soft errors may be reduced because any alpha particles emitted from the substrate and/or solder resist may not reach and/or penetrate the various components of the memory package.

However, as memory devices continue to shrink and/or operate on lower operating voltages, the memory devices may become more sensitive to soft errors. More particularly, as pitch size within a memory package decreases, electrical contacts may become smaller and/or closer together, resulting in smaller solder balls or other types of electrical joints and thus reduced standoff between integrated circuits and the substrate and/or solder resist. Accordingly, because the various components may be mounted nearer to one another, the integrated circuits may be more susceptible to soft errors resulting from alpha particle emissions of the substrate, solder resist, and other radioactive impurities in the semiconductor packaging

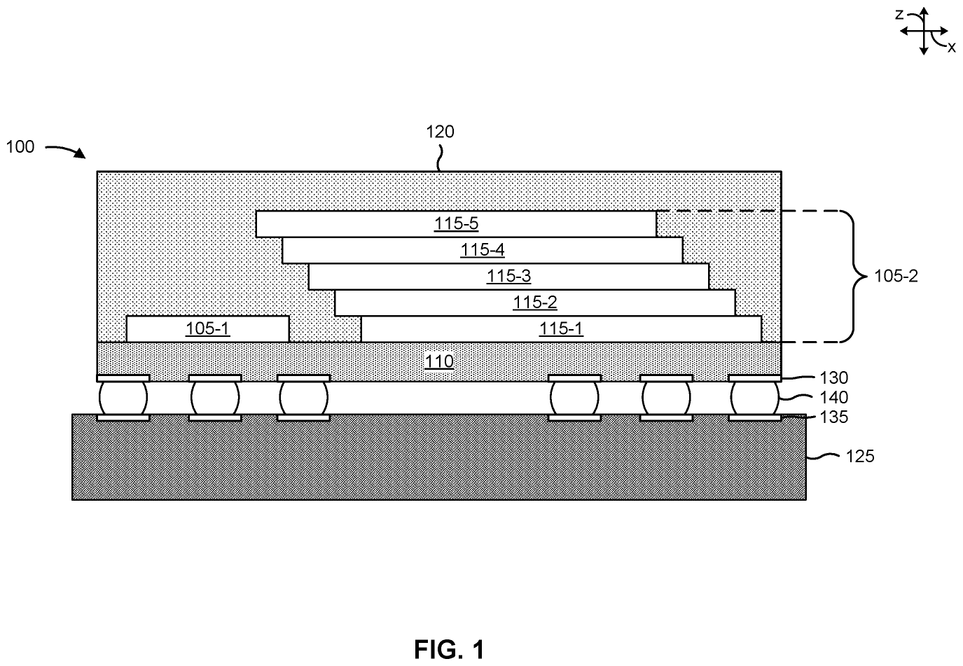

Some implementations described herein reduced soft errors caused by radioactive impurities in semiconductor packaging materials by providing an alpha particle shield between a substrate and/or a solder resist and an integrated circuit, such as a controller, a memory die, or other semiconductor die. In some implementations, the alpha particle shield may be a copper shield that may block and/or impede alpha particles such that the alpha particles do not penetrate an integrated circuit. In some implementations, the alpha particle shield may be disposed at an edge of a solder mask opening, which may otherwise be a source of alpha particle emissions. As a result, alpha particle penetration at an integrated circuit may be reduced or eliminated, resulting in an reduction of soft errors at a semiconductor device, and a corresponding reduction in power, computing, and other resource consumption that would otherwise be used for soft error correction processes. These and other features may be more readily understood with reference to FIGS. 1-9, described in more detail below.

FIG. 1 is a diagram of an example apparatus 100 that may be manufactured using techniques described herein. In FIG. 1 and the following figures, each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a synchronous dynamic RAM (SDRAM) device, a ferroelectric RAM (FeRAM) device, a magnetic RAM (MRAM) device, a resistive RAM (RRAM) device, a holographic RAM (HRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include one or more integrated circuits 105, shown as a first integrated circuit 105-1 and a second integrated circuit 105-2, disposed on a substrate 110. An integrated circuit 105 may include any type of circuit, such as an analog circuit, a digital circuit, a radiofrequency (RF) circuit, a power supply, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include multiple semiconductor dies 115 (sometimes called dies), shown as five semiconductor dies 115-1 through 115-5. As shown in FIG. 1, the dies 115 may be stacked on top of each other to reduce a footprint of the apparatus 100. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on.

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board (PCB). For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

As indicated above, FIG. 1 is provided as an example. Other examples may differ from what is described with regard to FIG. 1.

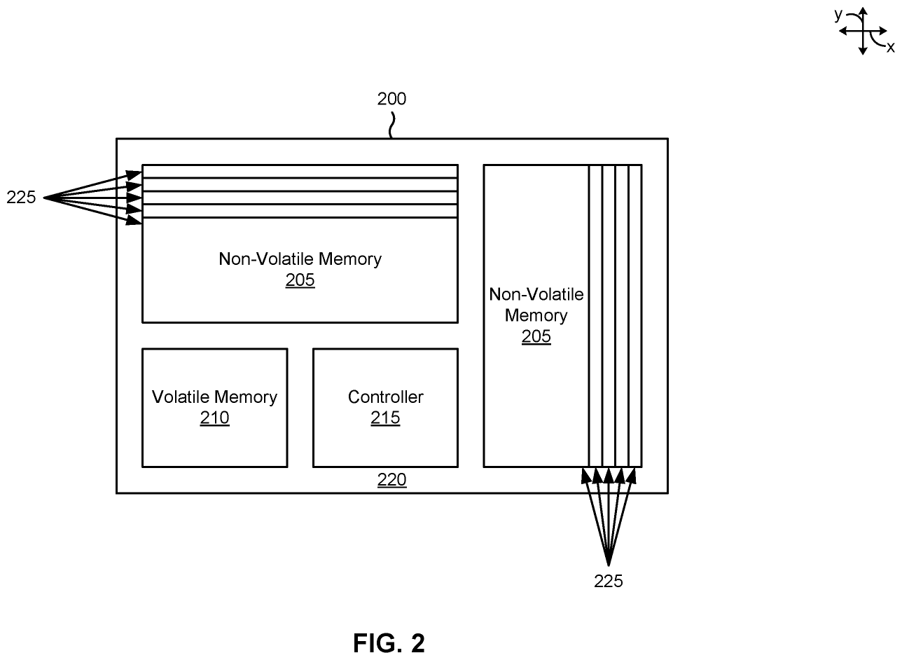

FIG. 2 is a diagram of an example memory device 200 that may be manufactured using techniques described herein. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes stacked semiconductor dies 225, as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM, SRAM, SDRAM, FeRAM, MRAM, RRAM, and/or HRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

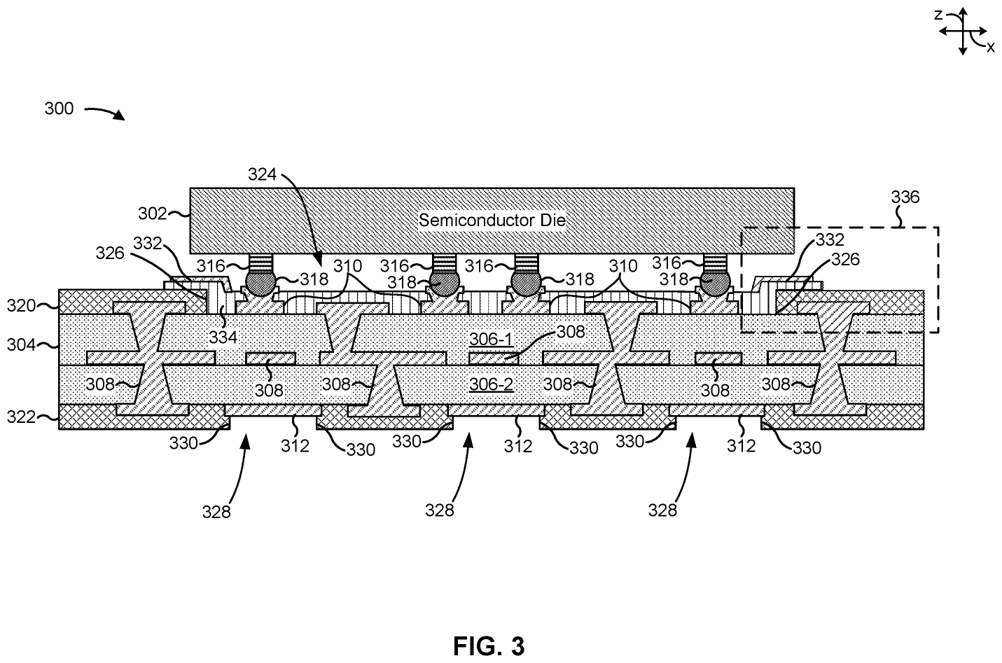

FIG. 3 is a diagram of an example apparatus 300 (e.g., memory device 200) that includes an alpha particle shield.

As shown in FIG. 3, the apparatus 300 may include a semiconductor die 302 (e.g., integrated circuit 105, semiconductor die 115, non-volatile memory 205, volatile memory 210, controller 215, or a similar die) bonded to a substrate 304 (e.g., substrate 220). In some implementations, the substrate may include multiple layers 306, shown in FIG. 3 as a first layer 306-1 and a second layer 306-2. The layers 306 may be manufactured from an epoxy and/or polymer material, and in some implementations, may include fibers pre-impregnated in the epoxy and/or polymer material (e.g., the layers may be formed from prepreg). Put another way, in some implementations, the substrate 304 may include multiple prepreg layers 306. In some implementations, each layer may be referred to, or may otherwise correspond to, a redistribution layer (RDL). Additionally, or alternatively, the substrate 304 may include multiple traces, channels, contacts, pads, terminals, or other electrical connections used to provide electrical connectivity throughout the substrate 304 and/or to components mounted to the substrate 304. For example, the substrate may include a plurality of traces 308 (e.g., copper and/or gold signal traces), a plurality of first electrical contacts 310 (e.g., copper and/or gold contacts), a plurality of second electrical contacts 312 (e.g., copper and/or gold contacts), and/or other electrical contacts and/or connections. In some implementations, the plurality of first electrical contacts 310 may be configured to form a bond with the semiconductor die 302, such as via corresponding bumps 316 (e.g., pillar bumps) and/or solder balls 318. The plurality of second electrical contacts 312 may be configured to form a bond with a PCB or a similar board, such as via solder balls, solder paste, or a similar bonding material placed between the plurality of second electrical contacts 312 and corresponding electrical contacts on the PCB or similar board.

In some implementations, the substrate 304 may further include one or more solder resist layers (sometimes referred to as a solder mask), such as solder resist 320 disposed on a top surface, in a z-axis direction, of the substrate 304, and solder resist 322 disposed on a bottom surface, in the z-axis direction, of the substrate 304. The solder resist 320, 322 may be a layer of polymer or similar material applied to the various electrical connections and/or contacts (e.g., copper traces and/or contacts) for protection against oxidation and/or to prevent solder bridges from forming between the electrical connections and/or contacts, among other benefits. In that regard, the solder resist 320 and/or the solder resist 322 may coat a respective surface of the substrate 304, and/or may include one or more openings in order to expose one or more electrical contacts. For example, the solder resist 320 may include an opening 324 defined by a plurality of edges 326, with the opening 324 exposing the plurality of first electrical contacts 310. Similarly, the solder resist 322 may include one or more openings 328 defined by a plurality of respective edges 330, with the one or more openings 328 exposing the plurality of second electrical contacts 312.

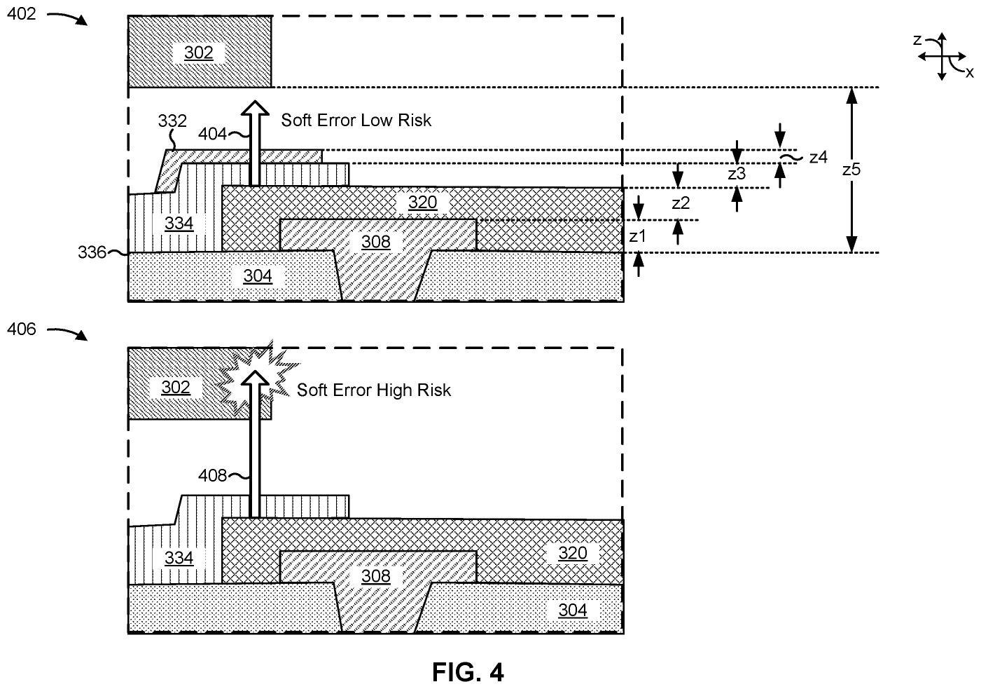

In some implementations, the solder resist 320 may at least partially overlap, in an x-axis direction and/or a y-axis direction, with the semiconductor die 302. More particularly, as shown in FIG. 3, due to the opening 324 provided in the solder resist 320, a majority of the semiconductor die 302 may not overlap, in the x-axis direction and/or the y-axis direction, with the solder resist 320 (e.g., a majority of the semiconductor die 302 may not be disposed above, in the y-axis direction, any portion of the solder resist 320). Nonetheless, at portion of the solder resist 320 proximate the edges 326 of the opening 324 may overlap with a portion of the semiconductor die 302 (which is described in more detail in connection with FIG. 4). Accordingly, if the solder resist include radioactive impurities (e.g., if the solder resist 320 includes ²³⁸U, ²³⁵U, ²³²Th, or a similar radioactive material), there is a risk of alpha particles penetrating the semiconductor die 302, thus causing soft errors.

Accordingly, in some implementations, the apparatus 300 may include one or more alpha particle shields 332 disposed between the solder resist 320 and the semiconductor die 302. The alpha particle shields 332 may be formed from a suitable material to impede alpha particles from traveling therethrough. For example, in some implementations, the one or more alpha particle shields 332 may be formed from copper. Moreover, in some implementations, the one or more alpha particle shields 332 may be of a suitable cross-sectional thickness in order to impede alpha particles from traveling therethrough. For example, the one or more alpha particle shields 332 may be between approximately 2 micrometers (μm) and approximately 10 μm thick. More particularly, in some implementations, at least a portion of the one or more alpha particle shields 332 may be disposed, in the z-axis direction, above the solder resist 320, and a thickness of the one or more alpha particle shields 332, in the z-axis direction, may be between approximately 2 μm and approximately 10 μm. In some implementations, the thickness of the one or more alpha particle shields 332 may be approximately 5 μm. In some other implementations, the thickness of the one or more alpha particle shields may be approximately 8 μm.

In some implementations, the one or more alpha particle shields 332 may be disposed proximate to at least one edge 326 of the plurality of edges 326 defining the opening 324 (e.g., the one or more alpha particle shields 332 may be disposed at a location in which the solder resist 320 overlaps with the semiconductor die 302). In this way, the one or more alpha particle shields 332 may be disposed, in the z-axis direction, between the solder resist 320 and the semiconductor die 302 and thus may form a barrier between the solder resist 320 and the semiconductor die 302 that impedes alpha particles emitted by the solder resist 320 and/or other components (e.g., the prepreg layers 306) from penetrating the semiconductor die 302. Put another way, the semiconductor die 302 may be disposed above, in the z-axis direction, the substrate 304 and may be electrically coupled to the substrate 304 via the plurality of first electrical contacts 310, and at least a portion of an alpha particle shield 332 may be disposed, in the z-axis direction, between the at least one edge 326 and the semiconductor die 302.

Additionally, or alternatively, as shown in FIG. 3, each alpha particle shield 332 may include a first substantially planar portion and a second substantially planar portion extending at an angle with respect to the first substantially planar portion (e.g., each alpha particle shield may include a substantially L-shaped cross-sectional area). In such implementations, the first substantially planar portion may extend substantially parallel to the outer surface of the substrate 304 (e.g., a surface of the substrate 304 including the plurality of first electrical contacts 310), and the second substantially planar portion may extend, from an edge of the first substantially planar portion, toward the opening 324 of the solder resist 320. In such implementations, the substantially L-shaped cross sectional area may serve to surround the solder resist 320 (e.g., may surround a corresponding corner provided at an edge 326 of the opening 324 provided in the solder resist 320), thereby further encapsulating and impeding any alpha particles emitted from radioactive impurities in the solder resist 320, which is described in more detail in connection with FIG. 4.

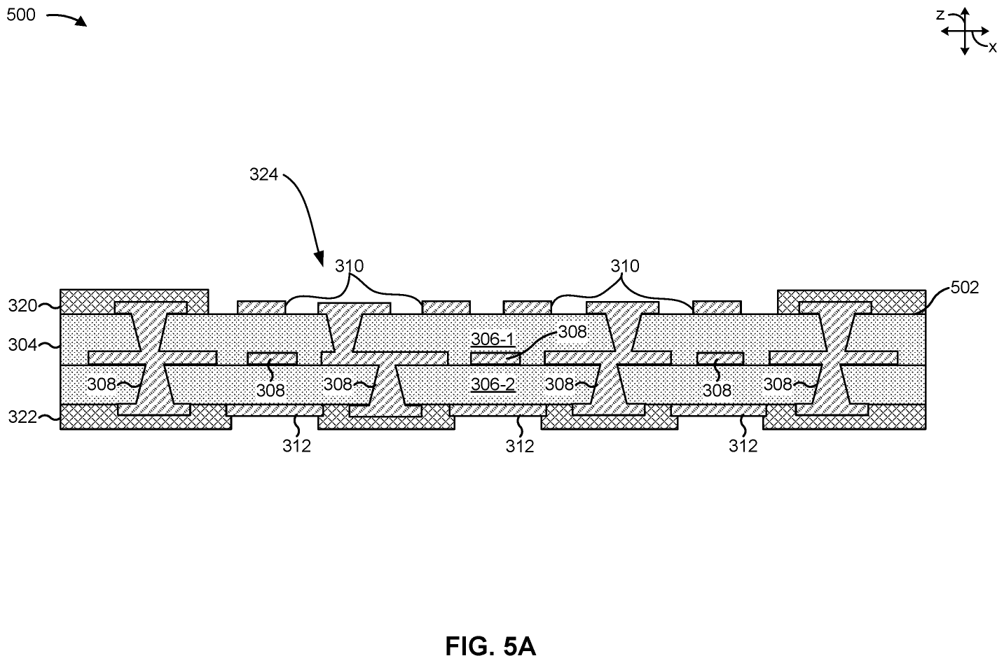

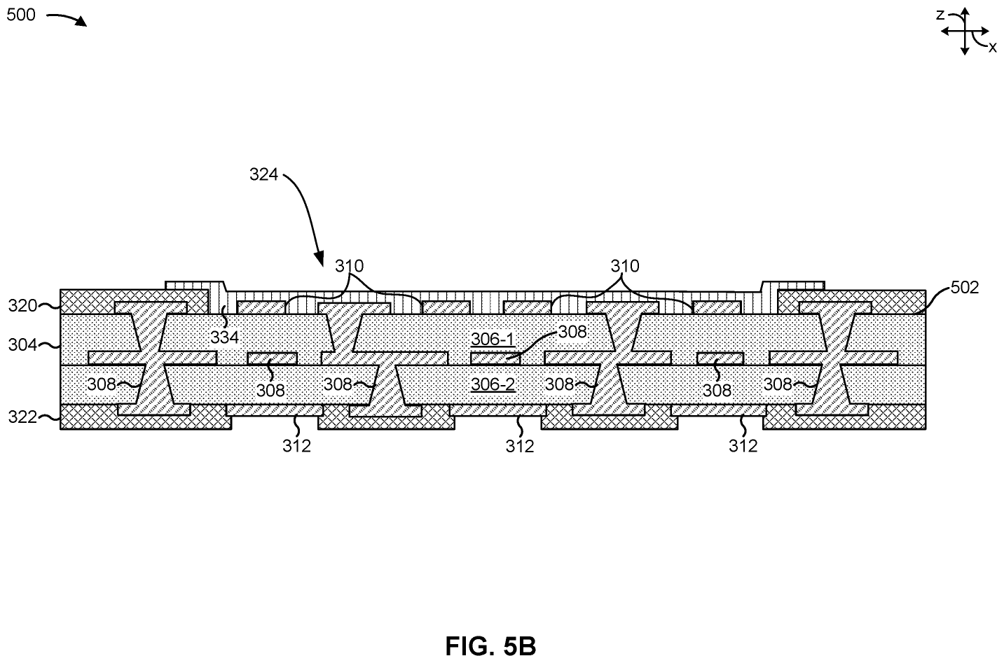

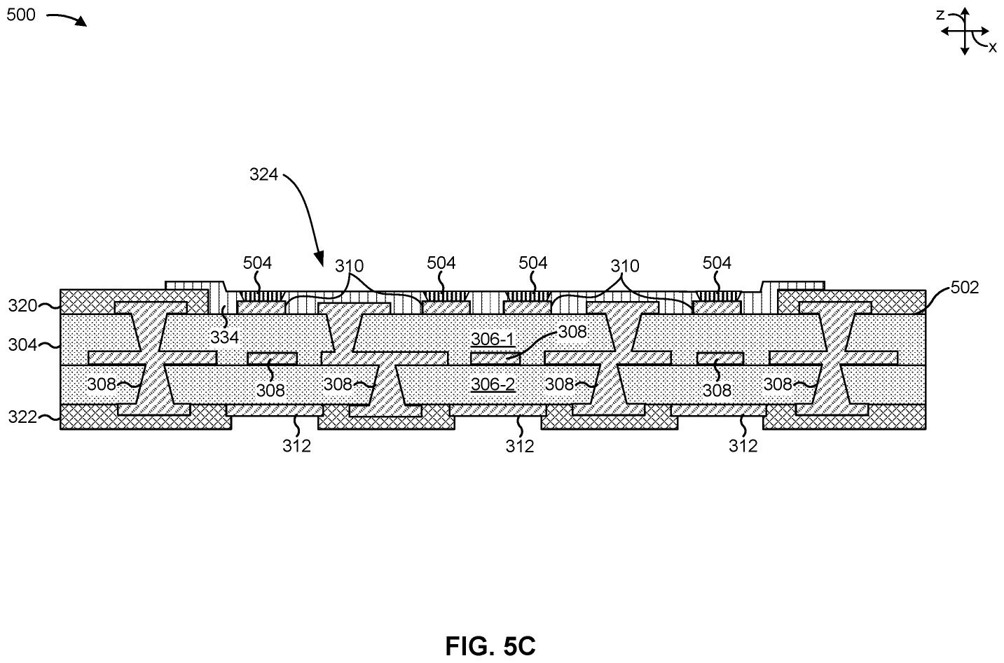

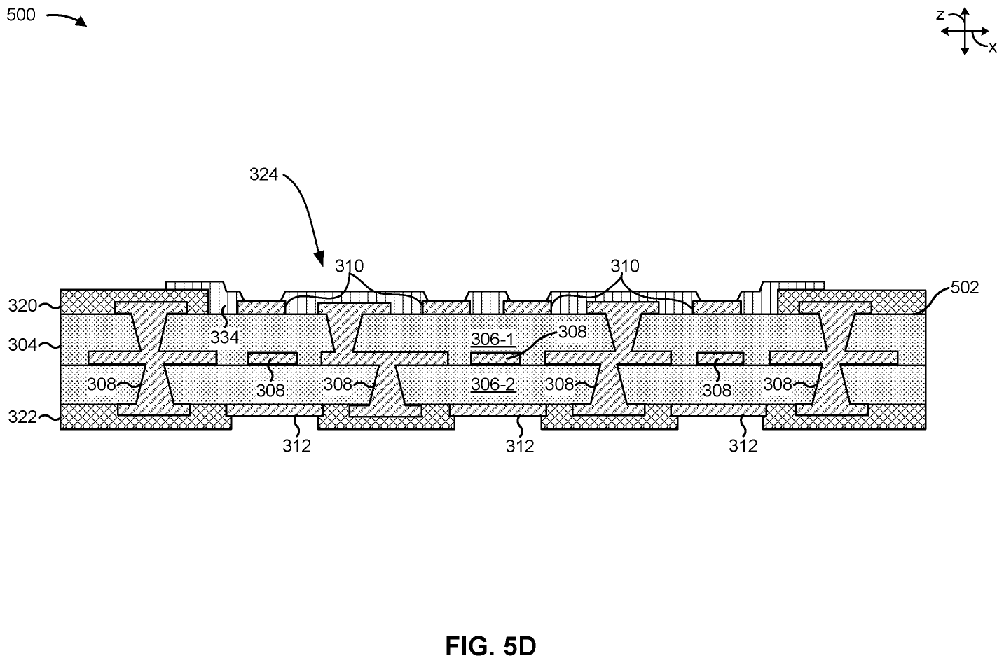

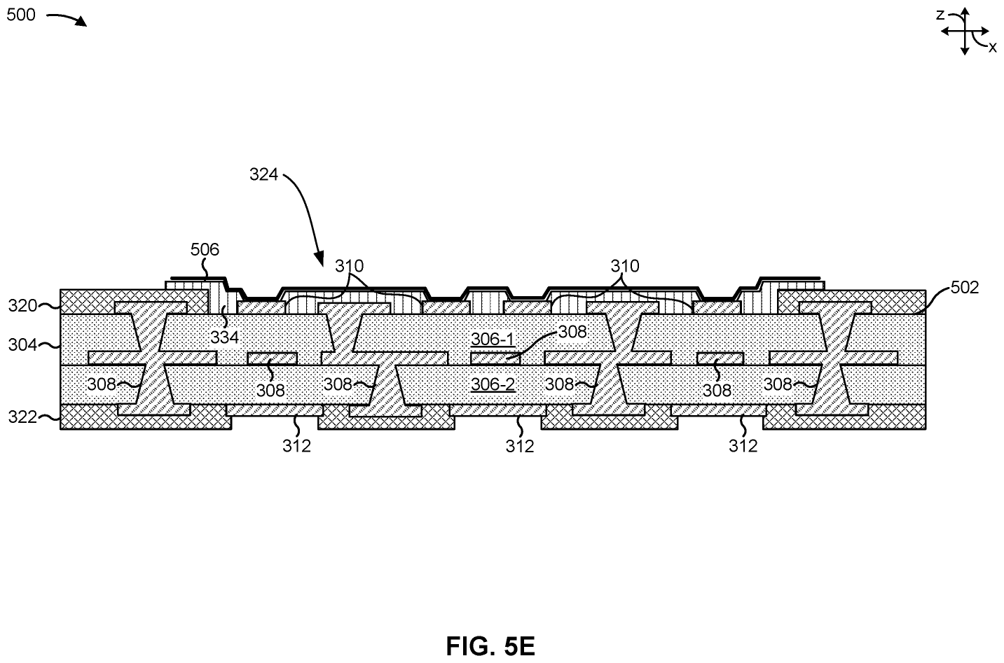

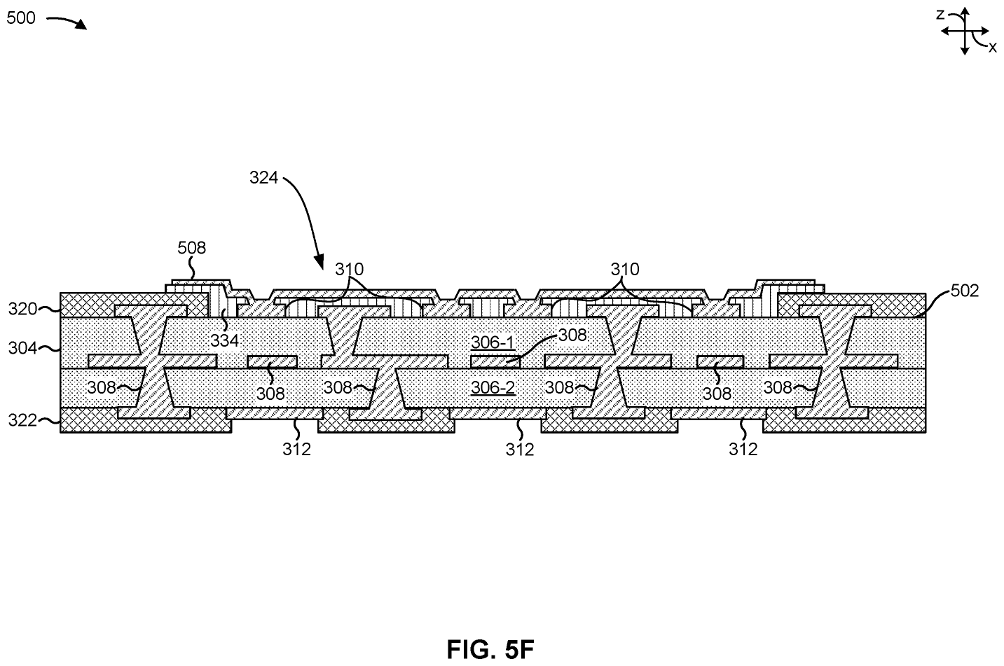

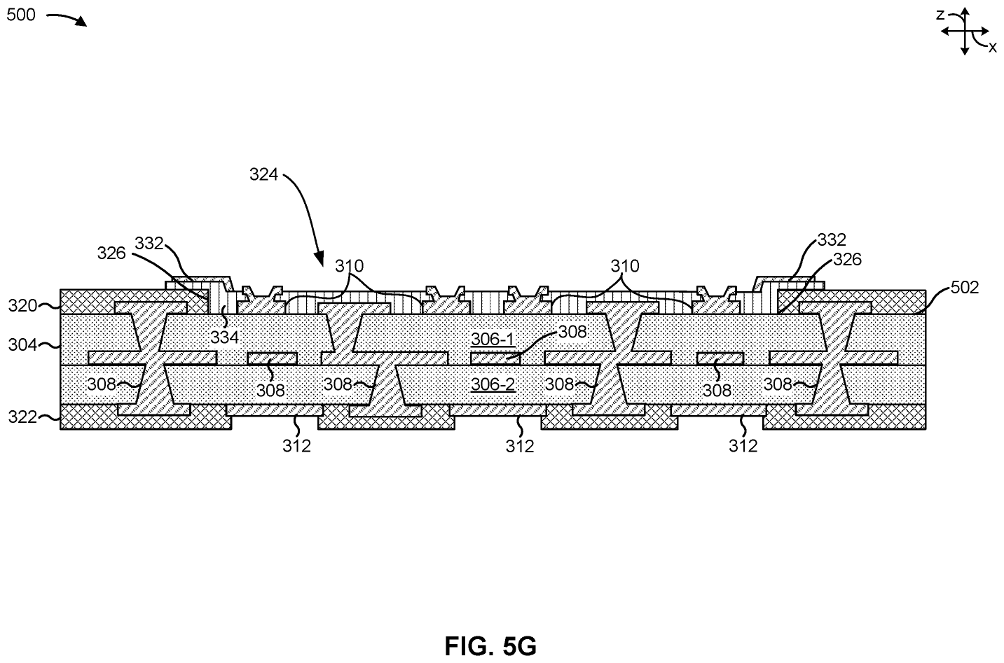

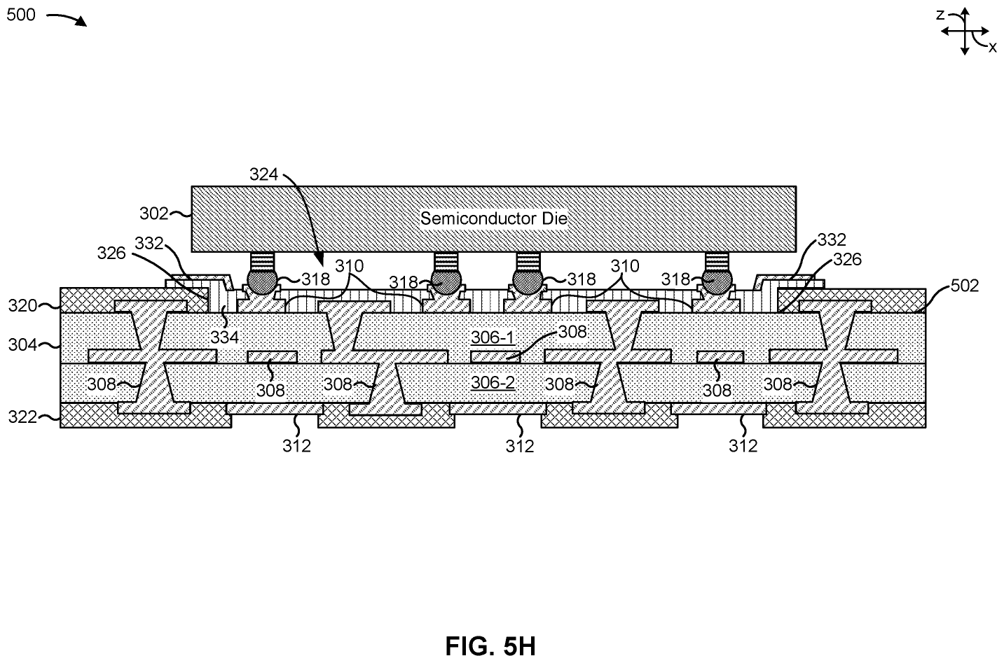

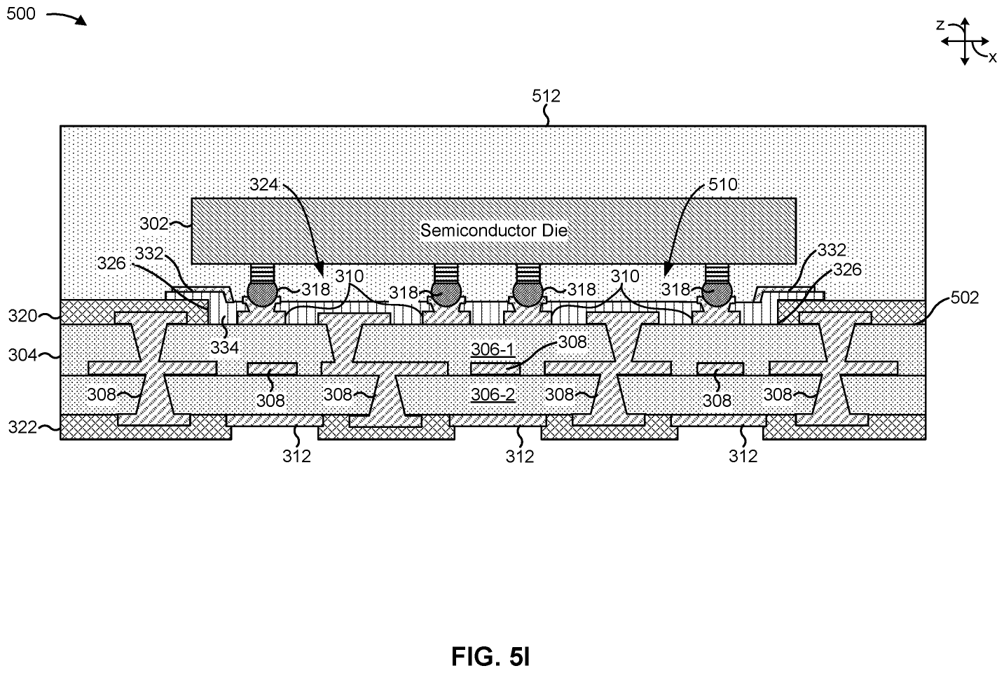

Additionally, in some implementations, the apparatus may include a polyimide layer 334 disposed on the outer surface of the substrate 304 (e.g., the surface including the plurality of first electrical contacts 310) and surrounding the plurality of first electrical contacts 310. In such implementations, the one or more alpha particle shields 332 may be coupled to the polyimide layer 334. Put another way, the polyimide layer 334 may be at least partially sandwiched between the solder resist 320 and the one or more alpha particle shields 332. In such implementations, the polyimide layer 334 may provide increased adhesion of an underfill material, a mold compound, or a similar filler material disposed between the semiconductor die 302 and the substrate 304, which is described in more detail in connection with FIG. 5I. Additionally, or alternatively, the polyimide layer 334 may further impede alpha particles emitted from radioactive impurities in the solder resist 320, the substrate 304, or other materials from penetrating the semiconductor die 302 and thus causing soft errors therein. This may be more readily understood with reference to FIG. 4, which is a close-up view of a portion 336 of the apparatus 300 denoted using a broken-line box indicated in FIG. 3.

As indicated above, FIG. 3 is provided as an example. Other examples may differ from what is described with respect to FIG. 3.

FIG. 4 is a diagram showing a close-up view of a portion of the apparatus 300 of FIG. 3. More particularly, FIG. 4 shows an example 402 of a close-up view of the portion 336 of the apparatus 300 enclosed by the broken-line box in FIG. 3. In that regard, the example 402 shows a portion of the substrate 304 including a partial trace 308 therein, a portion of the solder resist 320 disposed on an outer surface (e.g., an upper surface) of the substrate 304, a portion of the polyimide layer 334 disposed on the outer surface of the substrate 304, an alpha particle shield 332 disposed on a portion of the polyimide layer 334, and a portion of the semiconductor die 302 disposed above the alpha particle shield 332.

As indicated by the arrow 404, in some implementations, the solder resist 320 may emit alpha particles, such as from radioactive impurities in the solder resist 320. In this implementation, because the apparatus 300 includes the alpha particle shield 332 between the solder resist 320 and the semiconductor die 302, the alpha particles indicated by arrow 404 may be impeded (e.g., blocked and slowed) such that the alpha particles do not reach the semiconductor die 302 and/or do not penetrate the semiconductor die 302. In that regard, the alpha particle shield 332 may enable a soft error risk in the apparatus 300 to be reduced.

In contrast, example 406 in FIG. 4 is a close-up view of the portion 336 of the apparatus 300 enclosed by the broken-line box in FIG. 3, but shown with the alpha particle shield 332 omitted. In this case, and as indicated by arrow 408, alpha particles emitted from the solder resist 320 (e.g., alpha particles emitted from radioactive impurities in the solder resist 320) may reach the semiconductor die 302 and/or may penetrate the semiconductor die 302. In that regard, when the alpha particle shield 332 is omitted, there may be a high soft error risk to the semiconductor die 302.

In some implementations, a thickness of the alpha particle shield 332 (e.g., a dimension of the alpha particle shield 332 in the z-axis direction, indicated as 24 in FIG. 4) may be configured to sufficiently impede any alpha particles from reaching and/or penetrating the semiconductor die 302. For example, a thickness of a pad, terminal, or similar electrical connection associated with the trace 308 (indicated as z1 in example 402) may be approximately 15 μm, a thickness of the solder resist 320 above the pad, terminal, or similar electrical connection associated with trace 308 (indicated as 22 in example 402) may be approximately 10 μm (and thus an overall thickness of the solder resist 320, equal to z1+z2, may be approximately 25 μm), a thickness of the polyimide layer 334 above the solder resist 320 (indicated as z3 in example 402) may be approximately 5 μm, and a distance of the semiconductor die 302 above the substrate 304 (indicated as z5 in example 402) may be approximately 55 μm. In such examples, a thickness of the alpha particle shield 332 (indicated as 24 in example 402) may be between approximately 2 μm and approximately 10 μm. More particularly, in some implementations, a thickness of the alpha particle shield 332 (e.g., z4) may be approximately 5 μm, and in some other implementations, a thickness of the alpha particle shield 332 (e.g., z4) may be approximately 8 μm.

As indicated above, FIG. 4 is provided as an example. Other examples may differ from what is described with regard to FIG. 4.

FIGS. 5A-5I shows an example 500 of a manufacturing process that may be used to manufacture the apparatus 300 of FIG. 3.

A shown in FIG. 5A, the manufacturing process may include receiving the substrate 304. As described above in connection with FIG. 3, the substrate 304 may include the plurality of first electrical contacts 310 disposed on an outer surface 502 of the substrate 304 and the solder resist 320 disposed on the outer surface 502 of the substrate 304. Moreover, in some implementations, the solder resist 320 may include the opening 324 exposing the plurality of first electrical contacts 310.

As shown in FIG. 5B, the manufacturing process may include depositing the polyimide layer 334 on the substrate 304. Put another way, the substrate 304 may be laminated and/or coated with a photosensitive polyimide layer 334. In some implementations, the manufacturing process may include depositing the polyimide layer 334 within the opening 324 in the solder resist 320 such that the polyimide layer 334 surrounds the plurality of first electrical contacts 310 and at least partially overlaps the solder resist 320, as shown.

As shown in FIGS. 5C and 5D, the manufacturing process may include patterning and/or stripping the polyimide layer 334 (e.g., using a photolithography process) to expose the plurality of first electrical contacts 310. For example, as shown in FIG. 5C, the polyimide layer 334 may be exposed to a light and/or an energy source (e.g., a laser, an ultraviolet light source, an x-ray source, an electron beam sources, an ion beam source, or a similar light and/or energy source) and a mask, with the mask exposing portions 504 of the polyimide layer 334 that overlap the plurality of first electrical contacts 310 to the light and/or energy source and with the mask shielding other portions of the polyimide layer 334 from the light and/or energy source. Moreover, and as shown in FIG. 5D, the manufacturing process may include stripping the portions 504 of the polyimide layer 334 from substrate 304 to expose the plurality of first electrical contacts 310. More particularly, the portions 504 of the polyimide layer 334 that overlap the plurality of first electrical contacts 310 and which are exposed to the light and/or energy source may be stripped away, thus exposing the plurality of first electrical contacts 310.

As shown in FIG. 5E, the manufacturing process may include depositing a seed layer 506 on the polyimide layer 334 and the plurality of first electrical contacts 310. The seed layer 506 may be a thin layer deposited on a surface (e.g., the polyimide layer 334) prior to electroplating in order to improve adhesion of a copper layer or other material being electroplated. For example, in some implementations, the seed layer 506 may include a physical vapor deposition (PVD) copper seed layer. Moreover, as shown in FIG. 5F, the manufacturing process may include electroplating the polyimide layer 334, the seed layer 506, and/or the plurality of electrical contacts 310 with a copper layer 508. In some implementations, the copper layer 508 may form the basis of the one or more alpha particle shields 332. More particularly, as shown in FIG. 5G, the manufacturing process may include etching the copper layer 508 (e.g., using a photolithography process, or a similar process) to expose a portion of the polyimide layer 334 and to form the one or more alpha particle shields 332 disposed on the polyimide layer 334, proximate to the one or more edges 326 of the opening 324 in the solder resist 320.

In this way, the one or more alpha particle shields 332 may impede alpha particles emitted by radioactive impurities in the solder resist 320 or other materials from reaching and/or penetrating components mounted to the substrate 304 via the plurality of first electrical contacts 310 (e.g., the semiconductor die 302), as described above in connection with FIGS. 3-4. More particularly, as shown in FIG. 5H, the manufacturing process may include placing the semiconductor die 302 on the substrate 304 above, in the z-axis direction, the polyimide layer 334, and electrically coupling the semiconductor die 302 to the substrate 304 via the plurality of electrical contacts 310 (e.g., via the plurality of solder balls 318), such that the one or more alpha particle shields 332 are disposed between, in the z-axis direction, at least a portion of the solder resist 320 and at least a portion of the semiconductor die 302. In this way, the one or more alpha particle shields 332 may reduce a soft error risk, as described above in connection with FIG. 4.

Moreover, in some implementations, the manufacturing process may include filling a space 510 between the semiconductor die 302 and the polyimide layer 334 with an underfill material, such as a mold compound, a mold underfill (MUF), a capillary underfill, or a similar filler material. For example, as shown in FIG. 5I, the semiconductor die 302 may be encapsulated in a mold compound 512, such as during a compression molding process, or a similar process. In some other implementations, the semiconductor die 302 may be underfilled with an epoxy underfill material or the like, such as during a capillary underfill process. In such implementations, the presence of the polyimide layer 334 may improve adhesion of the underfill material to the substrate 304, thereby improving rigidity and longevity of the apparatus 300 and/or reducing the risk of the semiconductor die 302 loosening and/or detaching from the substrate 304.

As indicated above, FIGS. 5A-5I are provided as examples. Other examples may differ from what is described with respect to FIGS. 5A-5I.

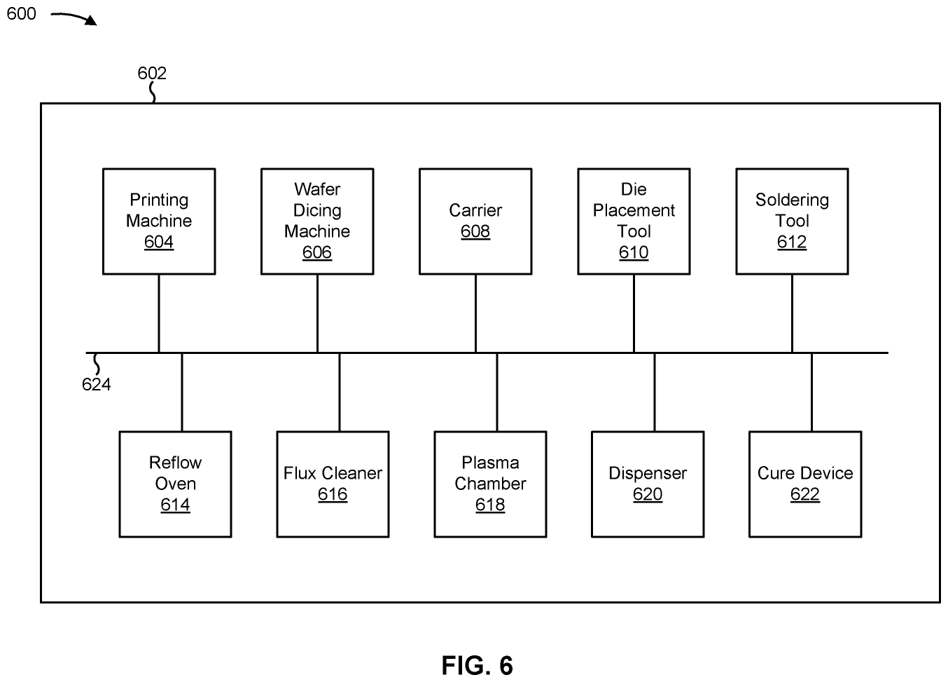

FIG. 6 is a diagram of example equipment 600 used to manufacture various semiconductor packages, memory devices, or similar components described herein. In some implementations, the equipment 600 may be used to manufacture apparatus 300 and/or a memory package or other semiconductor package including apparatus 300 (as described above in connection with FIGS. 5A-5I). As shown in FIG. 6, the equipment 600 may include a packaging system 602. The packaging system 602 may include one or more devices or tooling, such as a printing machine 604, a wafer dicing machine 606, a carrier 608, a die placement tool 610, a soldering tool 612, a reflow oven 614, a flux cleaner 616, a plasma chamber 618, a dispenser 620, and/or a cure device 622. One or more devices may be may physically or communicatively coupled to one another. For example, one or more devices may interconnect via wired connections and/or wireless connections, such as via a bus 624. Additionally, or alternatively, one or more devices may form part of an electronics assembly manufacturing line.

The printing machine 604 may be a device capable of printing patterns in a material such as silicon, a dielectric material, a polyimide layer, or a similar material, for purposes of forming an integrated circuit or the like. In some implementations, the printing machine 604 may be a lithography device capable of printing patterns in a material to form an integrated circuit. Additionally, or alternatively, the printing machine 604 may be capable of applying solder or other electrically conductive material to form a portion of an electrical connection to be formed between a die and a substrate. For example, the printing machine 604 may be capable of applying a grid of solder bumps to a die, which will align with a grid of bump pads on a substrate during a flip chip attachment process, or the like.

The wafer dicing machine 606 may be a device capable of dicing a die, such as a microcontroller, a memory die, or other semiconductor die, from a wafer. In some implementations, the wafer dicing machine 606 may include one or more blades and/or one or more lasers to dice a die from the wafer.

The carrier 608 may be a device capable of supporting and/or carrying a substrate during a die and/or chip attachment process, during a compression molding process, or during a similar process. The carrier 608 may be constructed from a non-contaminating material, such as quartz, glass, or a similar material, and may be capable of withstanding high temperatures. In that regard, the carrier 608 may be capable of carrying a substrate and/or one or more die through one or more ovens, such as a reflow oven 614 and/or a cure device 622.

The die placement tool 610 may be a high-precision tool capable of placing a die onto a substrate. In some implementations, the die placement tool 612 may be capable of flipping a flip chip die during a placement process, such that an active surface of the flip chip die, which may be facing up during preliminary manufacturing steps, may face the substrate during the flip chip die placement process. In some implementations, the die placement tool 610 may include one or more sensors capable of aligning bump bonds on a die with bond pads on a substrate during a flip chip die attachment process.

The soldering tool 612 may be capable of forming one or more solder connections between components of a semiconductor package. For example, the soldering tool 612 may be capable of forming wire bond connections between components of a semiconductor package by soldering wires connecting wire bond bands from one component to wire bond pads of another component. In some examples, the soldering tool 612 may be capable of applying a solder paste to between electrical contacts of electronic components, such as between pillar interconnects provided on a load switch and corresponding electrical contacts provided on a substrate.

The reflow oven 614 may be capable of heating components to a suitable temperature to cause a reflow of solder or other bonding material, thereby causing the solder or similar material to melt and make an electrical connection between two components.

The flux cleaner 616 may be a device capable of removing residual flux from a soldering process. In some implementations, the flux cleaner 616 may include a heater capable of removing residual flux through a heat treatment process. Additionally, or alternatively, the flux cleaner 616 may include a nozzle or similar device capable of applying a cleaning agent to a component in order to remove residual flux therefrom.

The plasma chamber 618 may be a device capable of providing plasma treatment to component. In some implementations, the plasma chamber 618 may be capable of directly or indirectly applying a plasma stream to an area of a component, such as for purposes of preparing the area on the component for receiving an epoxy underfill, or the like.

The dispenser 620 may be a device capable of dispensing a filler material around a die or similar component. In some implementations, the dispenser 620 may be capable of dispensing a mold compound (e.g., an epoxy mold compound) during a compression molding process. In some implementations, the dispenser 620 may include a dispensing needle capable of applying an epoxy underfill by capillary action under pressure, such as by dispensing underfill material around a periphery of a die and/or other electrical component such that the underfill material flows beneath the die and/or other electrical component and fills a space between the die and/or other electrical component and a substrate.

The cure device 622 may be a device capable of curing a mold compound, such as an epoxy mold compound, an epoxy underfill material, an MUF, or a similar material. In some implementations, the cure device 622 may be an oven configured to heat a mold compound to a suitable curing temperature. Additionally, or alternatively, the cure device 622 may be capable of curing a mold compound via a chemical reaction, by the application of ultraviolet light, by the application of other radiation, or the like.

The number and arrangement of devices and networks shown in FIG. 6 are provided as an example. In practice, there may be additional devices, fewer devices, different devices, or differently arranged devices than those shown in FIG. 6. Furthermore, two or more devices shown in FIG. 6 may be implemented within a single device, or a single device shown in FIG. 6 may be implemented as multiple, distributed devices. Additionally, or alternatively, a set of devices (e.g., one or more devices) of equipment 600 may perform one or more functions described as being performed by another set of devices of equipment 600.

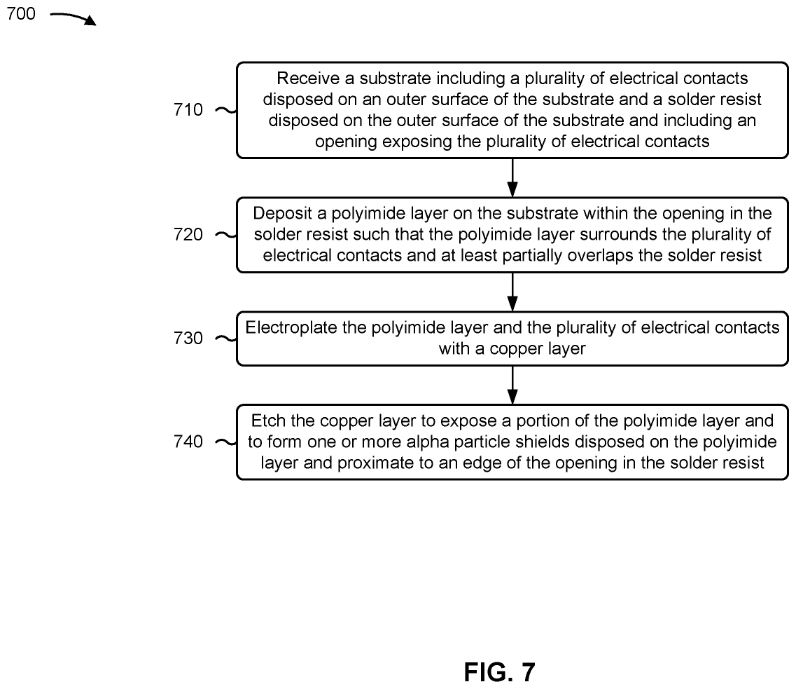

FIG. 7 is a flowchart of an example method 700 of forming an integrated assembly or memory device having an alpha particle shield. In some implementations, one or more process blocks of FIG. 7 may be performed by various semiconductor manufacturing equipment, such as the example equipment 600 described above in connection with FIG. 6.

As shown in FIG. 7, the method 700 may include receiving a substrate including a plurality of electrical contacts disposed on an outer surface of the substrate and a solder resist disposed on the outer surface of the substrate and including an opening exposing the plurality of electrical contacts (block 710). As further shown in FIG. 7, the method 700 may include depositing a polyimide layer on the substrate within the opening in the solder resist such that the polyimide layer surrounds the plurality of electrical contacts and at least partially overlaps the solder resist (block 720). As further shown in FIG. 7, the method 700 may include electroplating the polyimide layer and the plurality of electrical contacts with a copper layer (block 730). As further shown in FIG. 7, the method 700 may include etching the copper layer to expose a portion of the polyimide layer and to form one or more alpha particle shields disposed on the polyimide layer and proximate to an edge of the opening in the solder resist (block 740).

The method 700 may include additional aspects, such as any single aspect or any combination of aspects described below and/or in connection with one or more other methods described elsewhere herein.

In a first aspect, the method 700 includes placing a semiconductor die on the substrate above, in a direction, the polyimide layer, and electrically coupling the semiconductor die to the substrate via the plurality of electrical contacts, wherein the one or more alpha particle shields are disposed between, in the direction, at least a portion of the solder resist and at least a portion of the semiconductor die.

In a second aspect, alone or in combination with the first aspect, the method 700 includes filling a space between the semiconductor die and the polyimide layer with an underfill material.

In a third aspect, alone or in combination with one or more of the first and second aspects, the method 700 includes stripping a portion of the polyimide layer from substrate to expose the plurality of electrical contacts.

In a fourth aspect, alone or in combination with one or more of the first through third aspects, the method 700 includes depositing a seed layer on the polyimide layer and the plurality of electrical contacts prior to electroplating the polyimide layer and the plurality of electrical contacts with the copper layer.

Although FIG. 7 shows example blocks of the method 700, in some implementations, the method 700 may include additional blocks, fewer blocks, different blocks, or differently arranged blocks than those depicted in FIG. 7. In some implementations, the method 700 may include forming the apparatus 300, an integrated assembly that includes the apparatus 300, any part described herein of the apparatus 300, and/or any part described herein of an integrated assembly that includes the apparatus 300. For example, the method 700 may include forming one or more of the parts 302-334.

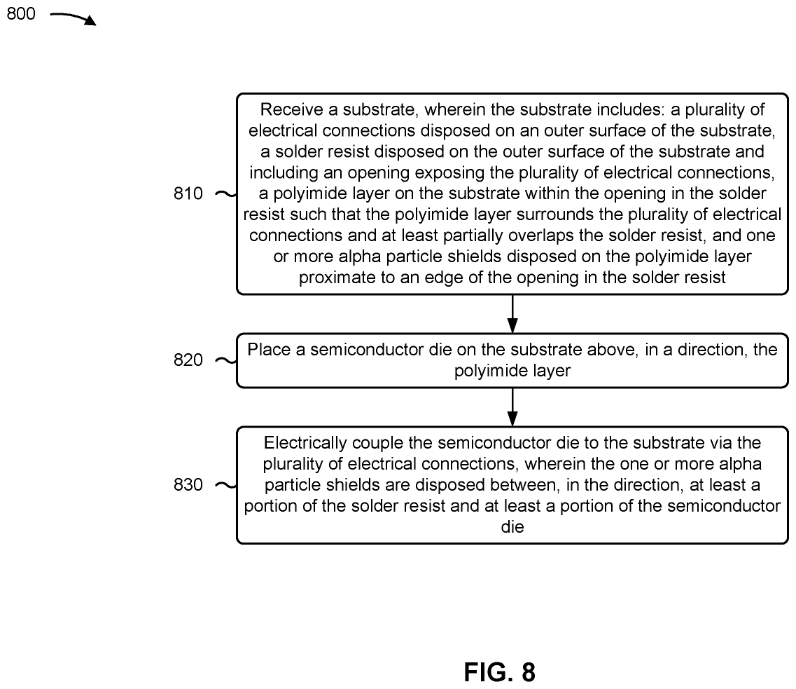

FIG. 8 is a flowchart of an example method 800 of forming an integrated assembly or memory device having an alpha particle shield. In some implementations, one or more process blocks of FIG. 8 may be performed by various semiconductor manufacturing equipment, such as the example equipment 600 described above in connection with FIG. 6.

As shown in FIG. 8, the method 800 may include receiving a substrate, wherein the substrate includes: a plurality of electrical contacts disposed on an outer surface of the substrate, a solder resist disposed on the outer surface of the substrate and including an opening exposing the plurality of electrical contacts, a polyimide layer on the substrate within the opening in the solder resist such that the polyimide layer surrounds the plurality of electrical contacts and at least partially overlaps the solder resist, and one or more alpha particle shields disposed on the polyimide layer proximate to an edge of the opening in the solder resist (block 810). As further shown in FIG. 8, the method 800 may include placing a semiconductor die on the substrate above, in a direction, the polyimide layer (block 820). As further shown in FIG. 8, the method 800 may include electrically coupling the semiconductor die to the substrate via the plurality of electrical contacts, wherein the one or more alpha particle shields are disposed between, in the direction, at least a portion of the solder resist and at least a portion of the semiconductor die (block 830).

The method 800 may include additional aspects, such as any single aspect or any combination of aspects described below and/or in connection with one or more other methods described elsewhere herein.

Although FIG. 8 shows example blocks of the method 800, in some implementations, the method 800 may include additional blocks, fewer blocks, different blocks, or differently arranged blocks than those depicted in FIG. 8. In some implementations, the method 800 may include forming the apparatus 300, an integrated assembly that includes the apparatus 300, any part described herein of the apparatus 300, and/or any part described herein of an integrated assembly that includes the apparatus 300. For example, the method 800 may include forming one or more of the parts 302-334.

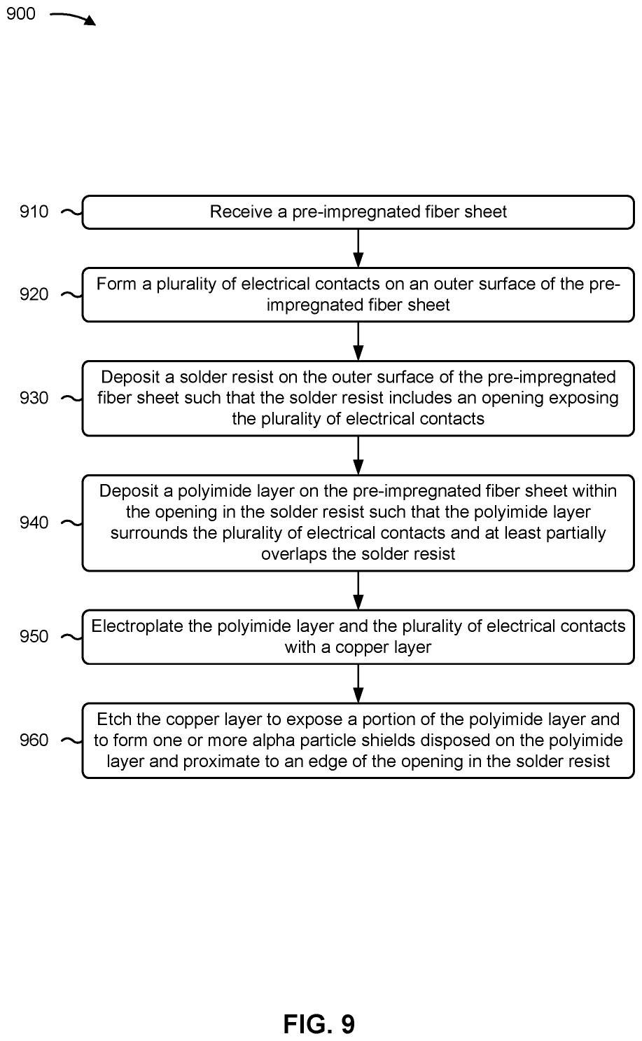

FIG. 9 is a flowchart of an example method 900 of forming an integrated assembly or memory device having an alpha particle shield. In some implementations, one or more process blocks of FIG. 9 may be performed by various semiconductor manufacturing equipment, such as the example equipment 600 described above in connection with FIG. 6.

As shown in FIG. 9, the method 900 may include receiving a pre-impregnated fiber sheet (block 910). As further shown in FIG. 9, the method 900 may include forming a plurality of electrical contacts on an outer surface of the pre-impregnated fiber sheet (block 920). As further shown in FIG. 9, the method 900 may include depositing a solder resist on the outer surface of the pre-impregnated fiber sheet such that the solder resist includes an opening exposing the plurality of electrical contacts (block 930). As further shown in FIG. 9, the method 900 may include depositing a polyimide layer on the pre-impregnated fiber sheet within the opening in the solder resist such that the polyimide layer surrounds the plurality of electrical contacts and at least partially overlaps the solder resist (block 940). As further shown in FIG. 9, the method 900 may include electroplating the polyimide layer and the plurality of electrical contacts with a copper layer (block 950). As further shown in FIG. 9, the method 900 may include etching the copper layer to expose a portion of the polyimide layer and to form one or more alpha particle shields disposed on the polyimide layer and proximate to an edge of the opening in the solder resist (block 960).

The method 900 may include additional aspects, such as any single aspect or any combination of aspects described below and/or in connection with one or more other methods described elsewhere herein.

Although FIG. 9 shows example blocks of the method 900, in some implementations, the method 900 may include additional blocks, fewer blocks, different blocks, or differently arranged blocks than those depicted in FIG. 9. In some implementations, the method 900 may include forming the apparatus 300, an integrated assembly that includes the apparatus 300, any part described herein of the apparatus 300, and/or any part described herein of an integrated assembly that includes the apparatus 300. For example, the method 900 may include forming one or more of the parts 302-334.

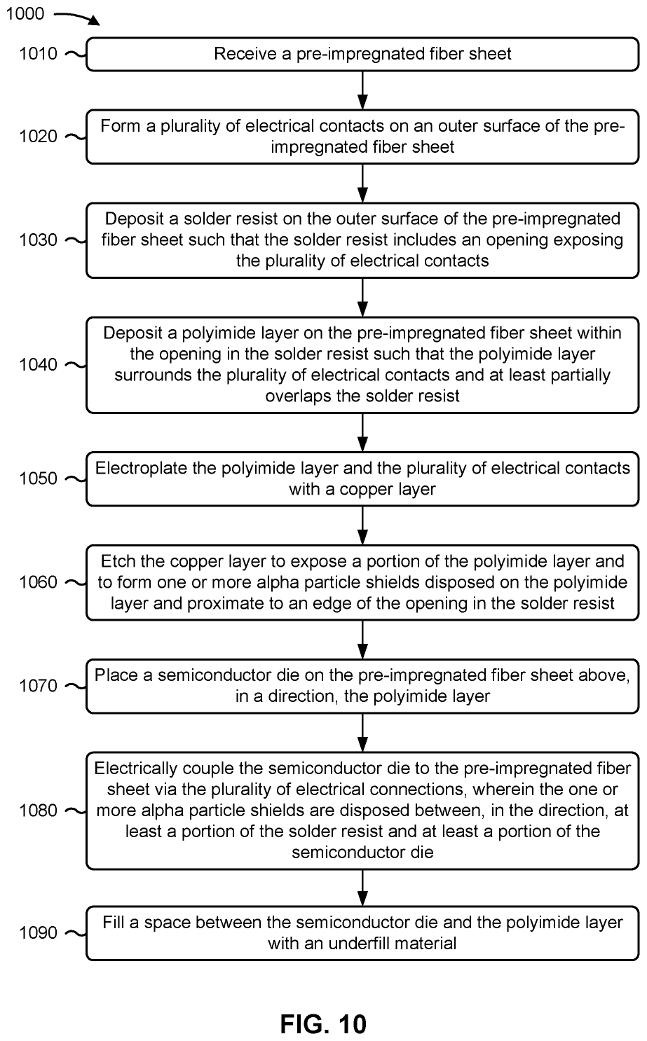

FIG. 10 is a flowchart of an example method 1000 of forming an integrated assembly or memory device having an alpha particle shield. In some implementations, one or more process blocks of FIG. 10 may be performed by various semiconductor manufacturing equipment, such as the example equipment 600 described above in connection with FIG. 6.

As shown in FIG. 10, the method 1000 may include receiving a pre-impregnated fiber sheet (block 1010). As further shown in FIG. 10, the method 1000 may include forming a plurality of electrical contacts on an outer surface of the pre-impregnated fiber sheet (block 1020). As further shown in FIG. 10, the method 1000 may include depositing a solder resist on the outer surface of the pre-impregnated fiber sheet such that the solder resist includes an opening exposing the plurality of electrical contacts (block 1030). As further shown in FIG. 10, the method 1000 may include depositing a polyimide layer on the pre-impregnated fiber sheet within the opening in the solder resist such that the polyimide layer surrounds the plurality of electrical contacts and at least partially overlaps the solder resist (block 1040). As further shown in FIG. 10, the method 1000 may include electroplating the polyimide layer and the plurality of electrical contacts with a copper layer (block 1050). As further shown in FIG. 10, the method 1000 may include etching the copper layer to expose a portion of the polyimide layer and to form one or more alpha particle shields disposed on the polyimide layer and proximate to an edge of the opening in the solder resist (block 1060). As further shown in FIG. 10, the method 1000 may include placing a semiconductor die on the pre-impregnated fiber sheet above, in a direction, the polyimide layer (block 1070). As further shown in FIG. 10, the method 1000 may include electrically coupling the semiconductor die to the pre-impregnated fiber sheet via the plurality of electrical contacts, wherein the one or more alpha particle shields are disposed between, in the direction, at least a portion of the solder resist and at least a portion of the semiconductor die (block 1080). As further shown in FIG. 10, the method 1000 may include filling a space between the semiconductor die and the polyimide layer with an underfill material (block 1090).

The method 1000 may include additional aspects, such as any single aspect or any combination of aspects described below and/or in connection with one or more other methods described elsewhere herein.

Although FIG. 10 shows example blocks of the method 1000, in some implementations, the method 1000 may include additional blocks, fewer blocks, different blocks, or differently arranged blocks than those depicted in FIG. 10. In some implementations, the method 1000 may include forming the apparatus 300, an integrated assembly that includes the apparatus 300, any part described herein of the apparatus 300, and/or any part described herein of an integrated assembly that includes the apparatus 300. For example, the method 1000 may include forming one or more of the parts 302-334.

In some implementations, a semiconductor device assembly includes a substrate; a plurality of electrical contacts disposed on an outer surface of the substrate; a solder resist disposed on the outer surface of the substrate and including an opening defined by a plurality of edges and exposing the plurality of electrical contacts; and an alpha particle shield disposed proximate to at least one edge, of the plurality of edges.

In some implementations, a memory device includes a substrate; a plurality of electrical contacts disposed on an outer surface of the substrate; a solder resist disposed on the outer surface of the substrate and at least partially surrounding the plurality of electrical contacts; a semiconductor die electrically coupled to the substrate via the plurality of electrical contacts; and an alpha particle shield disposed between at least a portion of the solder resist and at least a portion of the semiconductor die.

In some implementations, a method includes receiving a substrate including a plurality of electrical contacts disposed on an outer surface of the substrate and a solder resist disposed on the outer surface of the substrate and including an opening exposing the plurality of electrical contacts; depositing a polyimide layer on the substrate within the opening in the solder resist such that the polyimide layer surrounds the plurality of electrical contacts and at least partially overlaps the solder resist; electroplating the polyimide layer and the plurality of electrical contacts with a copper layer; and etching the copper layer to expose a portion of the polyimide layer and to form one or more alpha particle shields disposed on the polyimide layer and proximate to an edge of the opening in the solder resist.

In some implementations, a method includes receiving a substrate, wherein the substrate includes: a plurality of electrical contacts disposed on an outer surface of the substrate, a solder resist disposed on the outer surface of the substrate and including an opening exposing the plurality of electrical contacts, a polyimide layer on the substrate within the opening in the solder resist such that the polyimide layer surrounds the plurality of electrical contacts and at least partially overlaps the solder resist, and one or more alpha particle shields disposed on the polyimide layer proximate to an edge of the opening in the solder resist; placing a semiconductor die on the substrate above, in a direction, the polyimide layer; and electrically coupling the semiconductor die to the substrate via the plurality of electrical contacts, wherein the one or more alpha particle shields are disposed between, in the direction, at least a portion of the solder resist and at least a portion of the semiconductor die.

In some implementations, a method includes receiving a pre-impregnated fiber sheet; forming a plurality of electrical contacts on an outer surface of the pre-impregnated fiber sheet; depositing a solder resist on the outer surface of the pre-impregnated fiber sheet such that the solder resist includes an opening exposing the plurality of electrical contacts; depositing a polyimide layer on the pre-impregnated fiber sheet within the opening in the solder resist such that the polyimide layer surrounds the plurality of electrical contacts and at least partially overlaps the solder resist; electroplating the polyimide layer and the plurality of electrical contacts with a copper layer; and etching the copper layer to expose a portion of the polyimide layer and to form one or more alpha particle shields disposed on the polyimide layer and proximate to an edge of the opening in the solder resist.

In some implementations, a method includes receiving a pre-impregnated fiber sheet; forming a plurality of electrical contacts on an outer surface of the pre-impregnated fiber sheet; depositing a solder resist on the outer surface of the pre-impregnated fiber sheet such that the solder resist includes an opening exposing the plurality of electrical contacts; depositing a polyimide layer on the pre-impregnated fiber sheet within the opening in the solder resist such that the polyimide layer surrounds the plurality of electrical contacts and at least partially overlaps the solder resist; electroplating the polyimide layer and the plurality of electrical contacts with a copper layer; etching the copper layer to expose a portion of the polyimide layer and to form one or more alpha particle shields disposed on the polyimide layer and proximate to an edge of the opening in the solder resist; placing a semiconductor die on the pre-impregnated fiber sheet above, in a direction, the polyimide layer; electrically coupling the semiconductor die to the pre-impregnated fiber sheet via the plurality of electrical contacts, wherein the one or more alpha particle shields are disposed between, in the direction, at least a portion of the solder resist and at least a portion of the semiconductor die; and filling a space between the semiconductor die and the polyimide layer with an underfill material.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” All ranges described herein are inclusive of numbers at the ends of those ranges, unless specifically indicated otherwise.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a substrate;
a plurality of electrical contacts disposed on an outer surface of the substrate;
a solder resist disposed on the outer surface of the substrate and including an opening defined by a plurality of edges and exposing the plurality of electrical contacts; and
an alpha particle shield disposed proximate to at least one edge, of the plurality of edges.

2. The semiconductor device assembly of claim 1, further comprising a semiconductor die disposed above, in a direction, the substrate and electrically coupled to the substrate via the plurality of electrical contacts, wherein at least a portion of the alpha particle shield is disposed, in the direction, between the at least one edge and the semiconductor die.

3. The semiconductor device assembly of claim 1, further comprising a polyimide layer disposed on the outer surface of the substrate and surrounding the plurality of electrical contacts, wherein the alpha particle shield is coupled to the polyimide layer.

4. The semiconductor device assembly of claim 3, wherein at least a portion of the polyimide layer is disposed between the solder resist and the alpha particle shield.

5. The semiconductor device assembly of claim 1, wherein the alpha particle shield includes a first substantially planar portion and a second substantially planar portion extending at an angle with respect to the first substantially planar portion.

6. The semiconductor device assembly of claim 5, wherein the first substantially planar portion extends substantially parallel to the outer surface of the substrate, and wherein the second substantially planar portion extends, from an edge of the first substantially planar portion, toward the opening of the solder resist.

7. The semiconductor device assembly of claim 1, wherein the alpha particle shield is a copper shield.

8. The semiconductor device assembly of claim 1, wherein at least a portion of the alpha particle shield is disposed, in a direction, above the solder resist, and wherein a thickness of the alpha particle shield, in the direction, is between 2 micrometers and 10 micrometers.

9. The semiconductor device assembly of claim 8, wherein the thickness of the alpha particle shield is approximately 5 micrometers.

10. The semiconductor device assembly of claim 8, wherein the thickness of the alpha particle shield is approximately 8 micrometers.

11. A memory device, comprising:
a substrate;
a plurality of electrical contacts disposed on an outer surface of the substrate;
a solder resist disposed on the outer surface of the substrate and at least partially surrounding the plurality of electrical contacts;
a semiconductor die electrically coupled to the substrate via the plurality of electrical contacts; and
an alpha particle shield disposed between at least a portion of the solder resist and at least a portion of the semiconductor die.

12. The memory device of claim 11, wherein the solder resist includes an opening exposing the plurality of electrical contacts, and wherein the alpha particle shield is disposed at an edge of the opening.

13. The memory device of claim 11, further comprising a polyimide layer disposed on the outer surface of the substrate and surrounding the plurality of electrical contacts, wherein the alpha particle shield is coupled to the polyimide layer.

14. The memory device of claim 13, wherein at least a portion of the polyimide layer is disposed between the solder resist and the alpha particle shield.

15. The memory device of claim 11, wherein the alpha particle shield includes a first substantially planar portion and a second substantially planar portion extending at an angle with respect to the first substantially planar portion.

16. The memory device of claim 15, wherein the first substantially planar portion extends substantially parallel to the outer surface of the substrate, and wherein the second substantially planar portion extends, from an edge of the first substantially planar portion, toward the plurality of electrical contacts.

17. The memory device of claim 11, wherein the alpha particle shield is a copper shield.

18. The memory device of claim 11, wherein at least a portion of the alpha particle shield is disposed, in a direction, above the solder resist, and wherein a thickness of the alpha particle shield, in the direction, is between 2 micrometers and 10 micrometers.

19. The memory device of claim 18, wherein the thickness of the alpha particle shield is approximately 5 micrometers.

20. The memory device of claim 18, wherein the thickness of the alpha particle shield is approximately 8 micrometers.
